(19) United States
(12) Patent Application Publication
(10) Pub. No.: US 2014/0291791 A1
(43) Pub. Date: Oct. 2, 2014

(54) SOLID STATE IMAGING APPARATUS AND ELECTRONIC DEVICE

(71) Applicant: Sony Corporation, Tokyo (JP)

(72) Inventor: Atsushi Toda, Kanagawa (JP)

(73) Assignee: Sony Corporation, Tokyo (JP)

(21) Appl. No.: 14/225,045

(22) Filed: Mar. 25, 2014

(30) Foreign Application Priority Data
Apr. 1, 2013 (JP) 2013-076282

(51) Int. Cl. H01L 31/0232; H01L 31/09

(52) U.S. Cl. CPC H01L 31/02327; H01L 31/09
USPC 257/432

(57) ABSTRACT

Provided is a solid state imaging apparatus including a transparent substrate formed of a birefringent material having a high refractive index in a direction vertical to a light receiving surface and a low refractive index in a direction parallel to the light receiving surface, the transparent substrate being disposed on the light receiving surface, and an electronic device including the solid state imaging apparatus.

### CROSS REFERENCE TO RELATED APPLICATIONS

This application claims the benefit of Japanese Priority Patent Application JP 2013-076282 filed Apr. 1, 2013, the entire contents of which are incorporated herein by reference.

### BACKGROUND

The present technology relates to a solid state imaging apparatus and an electronic device, more particularly, to a solid state imaging apparatus and an electronic device that achieve a small pixel size and resolution improvement at low costs without limiting design freedom degree.

### SUMMARY

In recent years, pixels in an image sensor have been miniaturized. By miniaturizing the pixels, the number of the pixels per chip is increased. As a result, images having improved resolution are provided.

With the miniaturized pixels, a configuration is proposed that an intralayer lens or an optical waveguide is disposed so that sufficient light is incident on a light receiving section in each pixel (see Japanese Patent Application Laid-open Nos. 2003-203694, 2005-294749 and 2007-180208, for example).

A high resolution can be provided by reducing the pixel size only when ½ of resolving power is smaller than the pixel size. The resolution is determined by a diffraction limit or an aberration of an imaging lens disposed outside of the image sensor. When two point light sources having the same luminance are placed at the almost same position and imaging is made by a lens on an image sensor, imaging does not have a point but have peaks having some widths due to the diffraction limit or the aberration. The resolving power can be defined as a minimum discernible width between two peaks.

For example, Rayleigh limit is used. When a peak height is defined as 1 and the two peaks cross at 1/e (=0.368), a valley of a combined curve of the two peaks will be 0.735, that is the resolving limit. A distance between the two peaks is defined as the resolving power.

When the pixel size is greater than ½ of the resolving power, the resolving power is determined by the pixel size. This is defined by a Nyquist theorem. Here, a maximum frequency component included in an original signal is defined as f. When the original signal is gained at a frequency of 2f or more, the original signal can be fully restored.

In a common camera, the resolving power is rate limited by the diffraction limit of the lens if an F value is greater than 5.6, and the resolving power is rate limited by the aberration of the lens if the F value is lower than 5.6. The F value of the cameras mounted on a compact digital camera, a video camera and a mobile phone is often within a range of 1.2 to 5.6. It turns out that the resolving power is rate limited by the aberration of the lens.

The best resolution is provided when the F value is within a range of 5.6 to 8. At this moment, the resolving power is about 4 μm. By the Nyquist theorem, the pixel size will be 2 μm. It means that the resolution is saturated and the resolution gets no more better even if the pixel size is decreased.

For example, a technology is proposed that a transparent substrate having a refractive index of greater than 1 is adhered to an image sensor, whereby the resolving power rate limited by the diffraction limit or the resolving power rate limited by the aberration of the lens is decreased, which results in an improved resolution (see Japanese Patent Application Laid-open No. 2010-161180).

Also, a technology is proposed that an optical component is configured to have a flat plate section and a convex curved section and a waveguide is used in the flat plate section, thereby improving the resolution (see Japanese Patent Application Laid-open No. 2011-135096).

However, in the technology described in Japanese Patent Application Laid-open No. 2010-161180, the resolution is insufficiently improved if the glass substrate etc. is thicken to be mounted in a centimeter order. Therefore, an imaging lens system is limited.

In the technology described in Japanese Patent Application Laid-open No. 2011-135096, optical components should be adhered per pixel with good accuracy. Such a technological difficulty may increase costs.

As described above, in a solid state imaging apparatus including an image sensor and an optical system such as an imaging lens in the related art, there is a limitation to improve the resolution by changing a configuration of the image sensor (a semiconductor ship).

It is desirable to achieve a small pixel size and resolution improvement at low costs without limiting design freedom degree.

According to a first embodiment of the present technology, there is provided a solid state imaging apparatus including a transparent substrate formed of a birefringent material having a high refractive index in a direction vertical to a light receiving surface and a low refractive index in a direction parallel to a chip surface, the transparent substrate being disposed on the light receiving surface.

The birefringent material may have a refractive index ratio nₑ/nₒ of the high refractive index nₑ and the low refractive index nₒ of 1.1 or more.

The birefringent material may be an inorganic material.

The inorganic material may be crystal, TiO₂, calcite or lithium niobate.

The birefringent material may be an organic material.

The organic material may be polymethyl methacrylate (PMMA), polycarbonate resin (PC), polystyrene (PS), acrylonitrile styrene (AS resin) and polymethacrylic styrene (MS resin).

The birefringent material may have a dielectric multilayer structure where materials having different relative permittivities are combined.

The dielectric multilayer structure may be provided by combining the materials having different relative permittivities such that each area of the materials having the same relative permittivity is 500 nm or less.

The dielectric multilayer structure may be formed by arranging the materials having the same relative permittivity in a lattice, hexagon, octagon or columnar shape.

The birefringent material may have refractive index dispersion such that the refractive index is high to a light having a short wavelength and the refractive index is low to a light having a long wavelength.

The birefringent material may have an Abbe number of 40 or less.

According to a second embodiment of the present technology, there is provided an electronic device including a transparent substrate formed of a birefringent material having a high refractive index in a direction vertical to a light receiving surface and a low refractive index in a direction to a chip surface, the transparent substrate being disposed on the light receiving surface.

According to the first and second embodiments of the present technology, the transparent substrate formed of a birefringent material having a high refractive index in a direction vertical to a light receiving surface and a low refractive index in a direction parallel to a chip surface is disposed on the light receiving surface.

According to a third embodiment of the present technology, there is provided a solid state imaging apparatus including a transparent substrate formed of a material having refractive index dispersion such that the refractive index is high to a light having a short wavelength and the refractive index is low to a light having a long wavelength, the transparent substrate being disposed on the light receiving surface.

The material having refractive index dispersion may have an Abbe number of 40 or less.

The material having refractive index dispersion may be polycarbonate resin (PC), polystyrene (PS), acrylonitrile styrene (AS resin), polymethacrylic styrene (MS resin), a glass-based material or TiO₂.

According to a fourth embodiment of the present technology, there is provided an electronic device including a solid state imaging apparatus including a transparent substrate formed of a material having refractive index dispersion such that the refractive index is high to a light having a short wavelength and the refractive index is low to a light having a long wavelength, the transparent substrate being disposed on the light receiving surface.

According to the third and fourth embodiments of the present technology, the transparent substrate formed of a material having refractive index dispersion such that the refractive index is high to a light having a short wavelength and the refractive index is low to a light having a long wavelength is disposed on the light receiving surface.

According to the present technology, a small pixel size and resolution improvement at low costs without limiting design freedom degree can be achieved.

These and other objects, features and advantages of the present technology will become more apparent in light of the following detailed description of best mode embodiments thereof, as illustrated in the accompanying drawings.

### BRIEF DESCRIPTION OF DRAWINGS

FIG. 1 is a view for illustrating a resolving power of an image sensor;

FIG. 2 is an enlarged graph shown in FIG. 1 at a right side;

FIG. 3 is a graph showing a relationship between a resolving power and an F value of a lens which will be a criterion of a resolution in a common camera;

FIG. 4 is a perspective view showing a configuration of a solid state imaging apparatus according to an embodiment of the present technology;

FIG. 5 is a view for illustrating an aberration of an imaging lens system;

FIG. 6 is a view for illustrating a change in the aberration of the imaging lens system on which a birefringent transparent substrate is disposed;

FIG. 7 is an enlarged view of a sensor chip and the birefringent transparent substrate in FIG. 6;

FIG. 8 is a view for illustrating birefringence of the birefringent transparent substrate;

FIG. 9 is an enlarged view of a part of the birefringent transparent substrate;

FIG. 10 is a view for illustrating a relationship between an incident surface and a polarized direction;

FIG. 11 is a graph showing an incident angle dependency of a light reflectance of a p-wave polarized light and a light reflectance of an s-wave polarized light;

FIG. 12 is a graph showing an effect of birefringence;

FIG. 13 is another graph showing an effect of birefringence;

FIG. 14 is still another graph showing an effect of birefringence;

FIG. 15 is a schematic view for illustrating a mechanism of a birefringence expression of a polymer;

FIG. 16 is a view for illustrating a dielectric multilayer structure using materials having relative permittivity ∈₁ and relative permittivity ∈₂;

FIG. 17 is a view for illustrating the case that a light is obliquely incident on the dielectric multilayer structure;

FIGS. 18A, 18B and 18C show examples of the dielectric multilayer structure;

FIG. 19 is a perspective view showing a solid state imaging apparatus according to another embodiment of the present technology;

FIG. 20 is a view for illustrating chromatic aberration of an imaging lens system;

FIG. 21 is a view for illustrating a change of the chromatic aberration of the imaging lens system by disposing a transparent substrate having refractive index dispersion;

FIG. 22 is a graph showing a relationship between an Abbe number of the transparent substrate having refractive index dispersion and the chromatic aberration;

FIGS. 23A-C show a manufacturing process of forming the birefringent transparent substrate using the dielectric multilayer structure;

FIGS. 24A-C show another manufacturing process of forming the birefringent transparent substrate using the dielectric multilayer structure; and

FIG. 25 is a block diagram showing a configuration example of a camera apparatus as an electronic device according to the present technology.

### DETAILED DESCRIPTION OF EMBODIMENTS

Hereinafter, an embodiment of the present technology will be described with reference to the drawings.

Firstly, a resolving power will be described.

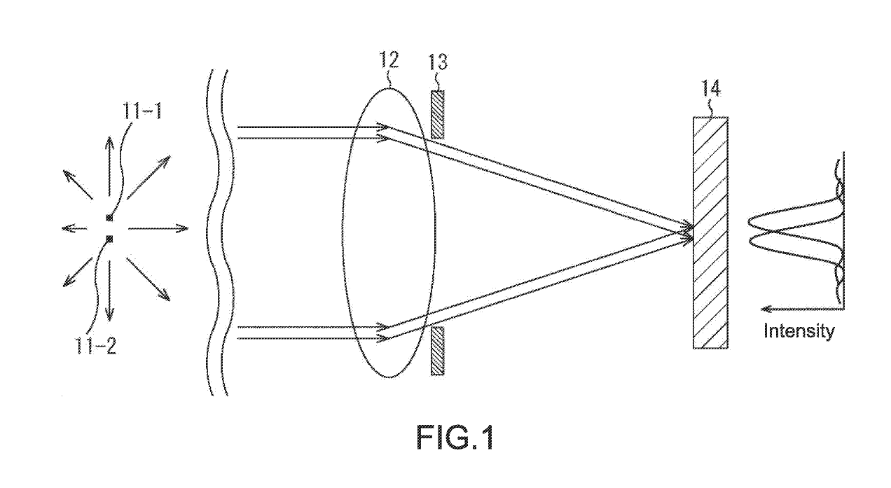

The resolving power of the image sensor is determined by the diffraction limit or the aberration of the imaging lens disposed outside the image sensor. FIG. 1 is a view for illustrating the resolving power.

As shown in FIG. 1, a point light source 11-1 and a point light source 11-2 having the same brightness are presented at almost the same distance from a light receiving surface of an image sensor 14. A light collected on the light-receiving surface of the image sensor 14 (a left side of the image sensor 14) through a lens 12 and a diaphragm 13 has a span, i.e., not a point but peaks, from the influence of the diffraction limit or the aberration. In the graph shown at a right side of FIG. 1, a horizontal axis represents an intensity of a light received and a vertical axis represents a position of the image sensor on the light receiving surface. The graph shows a change in the intensity of the light received from the two point light sources.

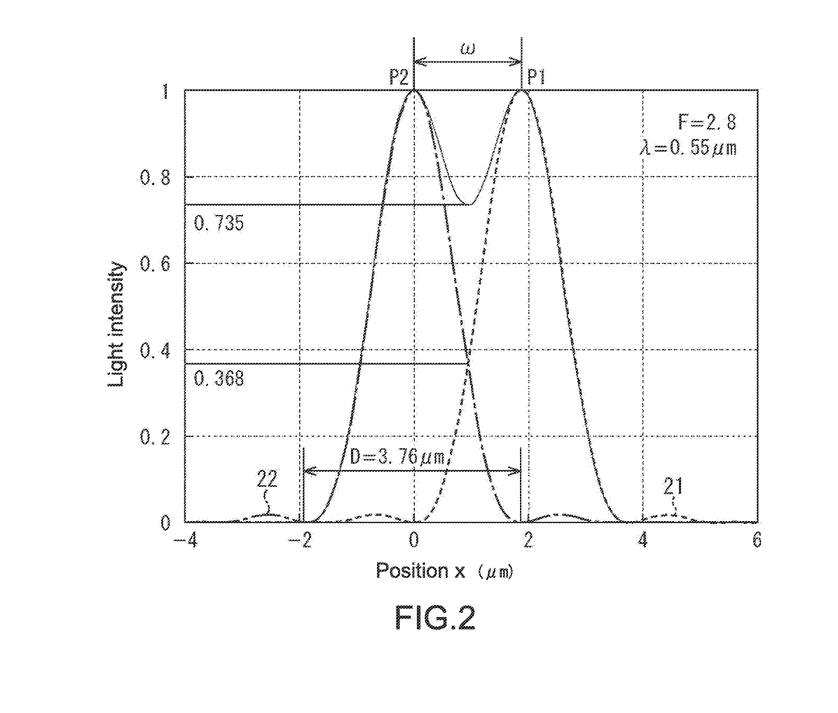

FIG. 2 is an enlarged graph shown in FIG. 1 at a right side. In FIG. 2, a horizontal axis represents the position on the light receiving surface, and a vertical axis represents the intensity of the light received. For example, a line 21 represents the change in the light intensity corresponding to the point light source 11-1 and a line 22 represents the change in the light intensity corresponding to the point light source 11-2, in FIG. 2.

The line 21 has a peak P1, and the line 22 has a peak P2. The resolving power is defined as a minimum discernible width between the two peaks P1 and P2.

Here, Rayleigh limit is used. When peak heights (light intensities) of the peaks P1 and P2 are defined as 1 and the lines 21 and 22 cross at 1/e (=0.368), a valley (the light intensity) of a combined curve of the two peaks will be 0.735, that is the resolving limit. A distance ω between the two peaks P1 and P2 is defined as the resolving power.

A high resolution can be provided by reducing the pixel size only when the pixel size is greater than ½ of the resolving power. By the Nyquist theorem, when the pixel size is greater than ½ of the resolving power, the resolving power is determined by the pixel size. According to the Nyquist theorem, a maximum frequency component included in an original signal is represented by f. When the original signal is gained at a frequency of 2f or more, the original signal can be fully restored.

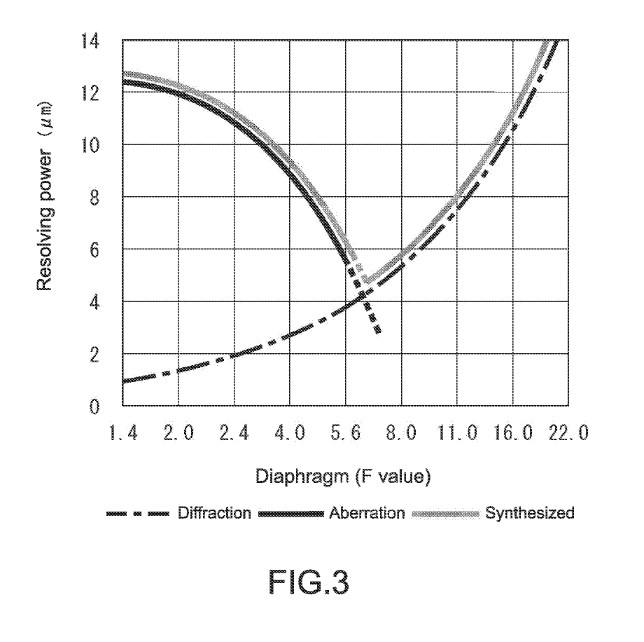

FIG. 3 is a graph showing a relationship between a resolving power and an F value of a lens which will be a criterion of a resolution in a common camera. In FIG. 3, a horizontal axis represents the F value, and a vertical axis represents the resolving power. The graph shows a change in the resolving power by the diffraction of the light passing through the lens, a change in the resolving power by the aberration of the light passing through the lens, and a change in the resolving power provided by combining them.

As shown in FIG. 3, the resolving power is rate limited by the diffraction limit of the lens when the F value is greater than 5.6, and the resolving power is rate limited by the aberration of the lens when the F value is lower than 5.6. The F value of the cameras mounted on a compact digital camera, a video camera and a mobile phone is often within a range of 1.2 to 5.6. It turns out that the resolving power is rate limited by the aberration of the lens of these cameras.

Also, as shown in FIG. 3, the best resolution is provided when the F value is within a range of 5.6 to 8. At this moment, the resolving power is about 4 μm. It means that the resolution is saturated. Accordingly, the pixel size of the cameras mounted on a compact digital camera, a video camera and a mobile phone is 2 (=4(½)) μm. It means that the resolution is saturated and the resolution gets no more better even if the pixel size is decreased.

For example, a technology is proposed that an embedded layer having a refractive index (n>1) greater than that of air (refractive index 1) is disposed at a part of a space between the lens and the image sensor.

By using such a configuration, the refractive index can be increased without changing a view angle θ from the lens 12, thereby more decreasing the resolving power at the diffraction limit (the distance ω in FIG. 2). Thus, the limitation of the pixel size can be decreased while providing high resolution images.

However, to attain such a configuration and sufficiently improve the resolution, the glass substrate etc. to be mounted should be thicken in a centimeter order. Thus, the imaging lens system is limited.

Also, a technology is proposed that a material having a high refractive index is disposed in contact with the light receiving surface of the image sensor as an optical component having a convex curved section (a spherical surface or a cylindrical surface) at a bottom.

By using such a configuration, a space around the curved section has the refractive index lower than that of the curved section. Therefore, the light incident on the curved section proceeds inside of the curved section, is narrowed to be a near-field light, and is incident on the light receiving surface. Thus, it is possible to avoid the influence of the diffraction limit or the aberration.

However, to attain such a configuration, the optical component should be adhered per pixel with good accuracy. Such a technological difficulty may increase costs.

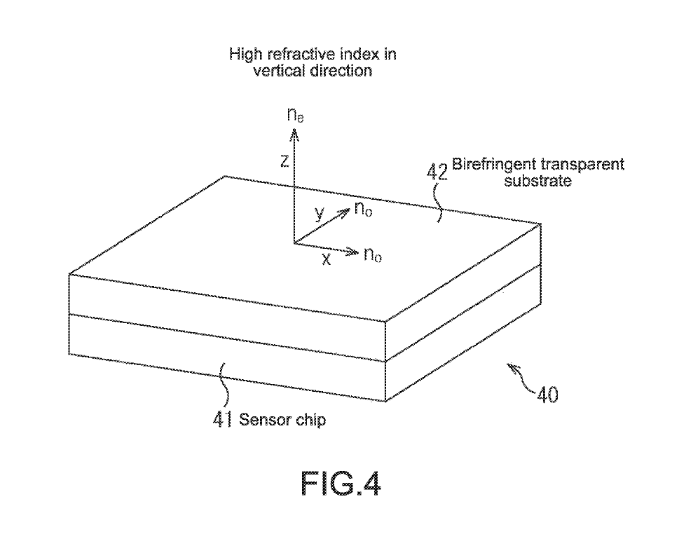

FIG. 4 is a perspective view showing a configuration of a solid state imaging apparatus (an image sensor) according to an embodiment of the present technology. In FIG. 4, an image sensor 40 includes a sensor chip 41, and a birefringent transparent substrate 42 disposed on a light receiving surface of the sensor chip 41.

Herein, birefringence represents a property having different refractive indices corresponding to light beam directions transmitting a member.

Examples of a material having the birefringence include inorganic materials such as quartz (crystal), TiO₂, calcite and lithium niobate. Also, organic materials such as polymethylmethacrylate (PMMA), polycarbonate resin (PC), polystyrene (PS), acrylonitrile styrene (AS resin) and polymethacryl styrene (MS resin) can be used. Alternatively, a material having a dielectric multilayer structure where materials having different specific dielectric constants are combined can be used.

The birefringent transparent substrate 42 has a refractive index nₑ to polarized light components of light beams in a vertical direction (a z axis direction) and a refractive index nₒ (<nₑ) to polarized light components of light beams in horizontal directions (an x axis direction and an y axis direction). In other words, when the birefringent transparent substrate 42 is disposed on the light receiving surface of the sensor chip 41, the direction of the high refractive index nₑ is adjusted to be vertical to the light receiving surface, and the direction of the low refractive index nₒ is adjusted to be parallel to the light receiving surface.

By using the configuration shown in FIG. 4, the aberration of the imaging lens system can be effectively reduced and the resolution can be improved.

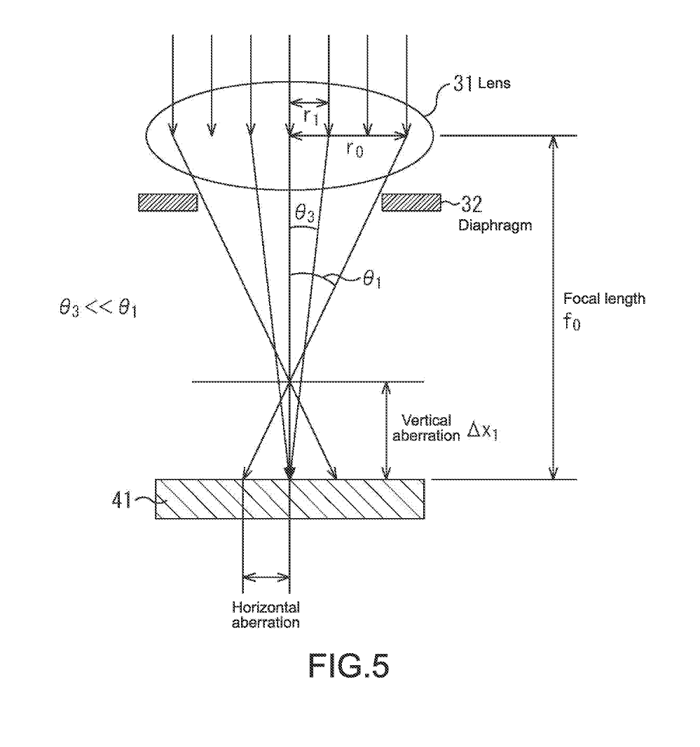

FIG. 5 is a view for illustrating the aberration of the imaging lens system. Herein, spherical aberration will be mainly described.

In FIG. 5, a lens 31 corresponds to the imaging lens system. The light collected by the lens 31 reach the light receiving surface of the sensor chip 41 via a diaphragm 32. Herein, no birefringent transparent substrate 42 is disposed.

In FIG. 5, a light axis is represented by a straight line passing through a center of the lens 31 and reaching a nearly center of the light receiving surface of the sensor chip 41. θ₁ represents an incident angle of the light beam passing through near an end of the lens (near the diaphragm 32). θ₃ (<<θ₁) represents an incident angle of the light beam around the light near the light axis. r₀ represents a distance from the light beam passing through near the end of the lens to the light beam in a thickness center of the lens 31. r₁ represents a distance from the light beam around the light axis to the light axis in a thickness center of the lens 31. f₀ represents a focal length of the lens 31.

As there is the aberration between the light beam around the light axis passing through the center of the lens 31 and the light beam passing through the end of the lens at near the diaphragm, the focal points are deviated. The light beam passing through near the end of the lens has the focal length shorter than that of the light beam around the light axis. When the light beam is then focused around the light axis, the focal point of the light beam passing through near the end of the lens is deviated and the aberration is generated.

As shown in FIG. 5, the aberration in the direction vertical to the light receiving surface is defined as a vertical aberration Δx₁. In contrast, the aberration in the direction parallel to the light receiving surface is defined as a horizontal aberration Δy₁. A relationship between the horizontal aberration and the vertical aberration is represented by the following numerical equation (1).

[Numerical Equation 1]

Δy₁=Δx₁ Tan θ₁ (1)

Also, there is a parameter of a blur (Bokeh) amount equivalent to the resolving power. The blur amount ∈₃ is represented by the following numerical equation (2).

[Numerical Equation 2]

∈S=1/4Δy₁ (2)

In addition, the vertical aberration is represented by the following numerical equation (3).

[Numerical Equation 3]

Δx₁=r₁/Tan θ₃−r₀/Tan θ₁ (3)

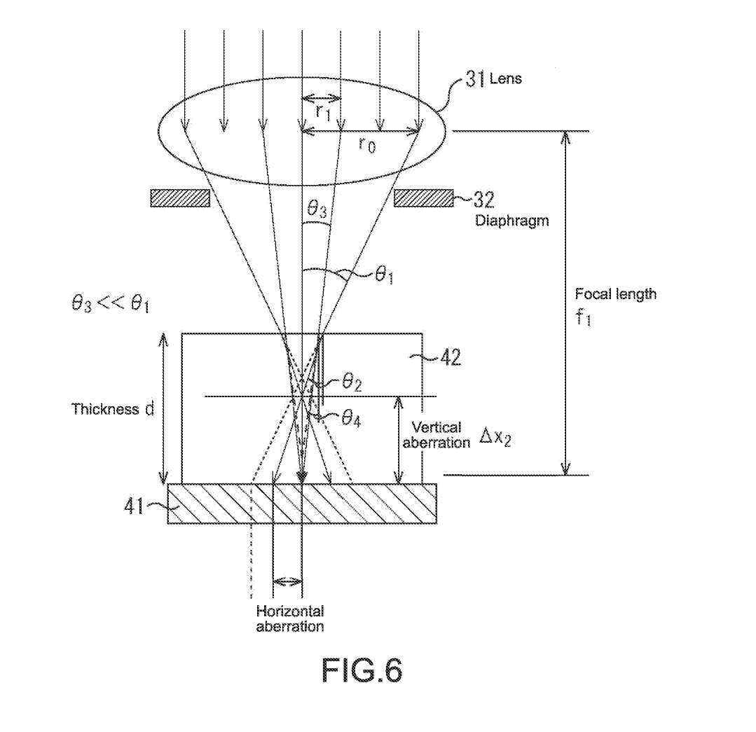

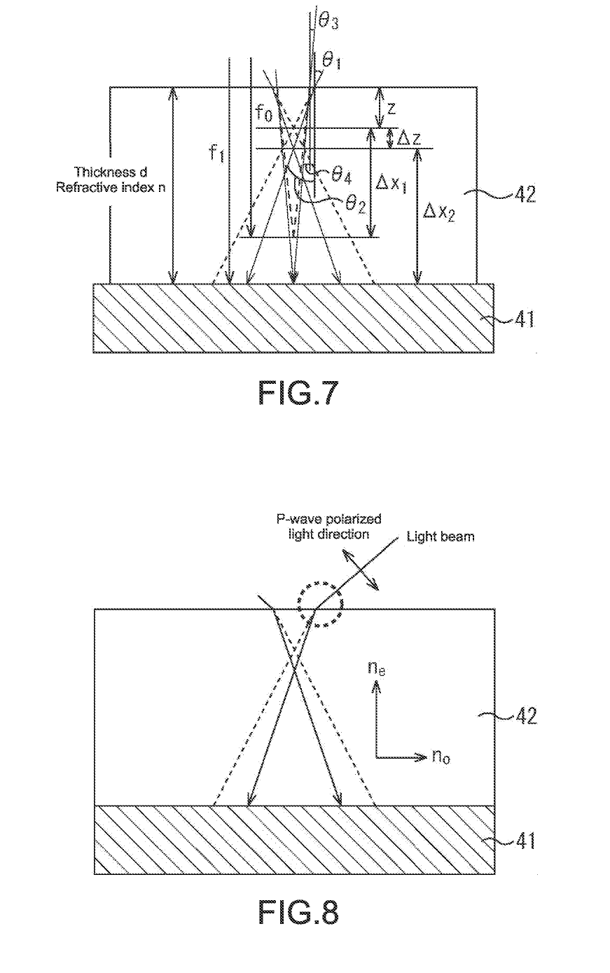

FIG. 6 is a view for illustrating a change in the aberration of the imaging lens system on which the birefringent transparent substrate 42 is disposed. As shown in FIG. 6, the birefringent transparent substrate 42 is disposed on the light receiving surface of the sensor chip 41. FIG. 7 is an enlarged view of the sensor chip 41 and the birefringent transparent substrate 42 in FIG. 6. As described above, in the birefringent transparent substrate 42, the direction of the high refractive index nₑ is adjusted to be vertical to the light receiving surface, and the direction of the low refractive index nₒ is adjusted to be parallel to the light receiving surface.

In FIGS. 6 and 7, the light axis is represented by a straight line passing through the center of the lens 31 and reaching a nearly center of the light receiving surface of the sensor chip 41. θ₁ represents the incident angle of the light beam passing through near the end of the lens (the diaphragm 32). θ₃ (<<θ₁) represents the incident angle of the light beam around the light near the light axis. rₒ represents the distance from the light beam passing through near the end of the lens to the light beam in the thickness center of the lens 31. r₁ represents the distance from the light beam around the light axis to the light axis in the thickness center of the lens 31.

Also, in FIGS. 6 and 7, f₀ represents the focal length of the lens 31, and f₁ represents the focal length of the lens 31 when the birefringent transparent substrate 42 is disposed. d represents a thickness of the birefringent transparent substrate 42. θ₂ represents an incident angle of the light beam within the birefringent transparent substrate 42 passing through near the end of the lens, and θ₄ represents an incident angle of the light beam within the birefringent transparent substrate 42 around the light near the light axis.

When the horizontal aberration and the vertical aberration in FIGS. 6 and 7 are represented as Δx₂ and Δy₂, a relationship between the horizontal aberration and the vertical aberration is represented by the following numerical equation (4).

[Numerical Equation 4]

Δy₂=Δx₂*Tan θ₂ (4)

The focal length f₁ is represented by the following numerical equation (5).

[Numerical Equation 5]

f₁=(r₁−d*Tan θ₄)/Tan θ₃+d (5)

Here, a distance from the outermost surface (an upper surface in FIGS. 6 and 7) of the birefringent transparent substrate 42 to the focal point of the light beams (dotted lines in FIGS. 6 and 7) passing through near the end of the lens is defined as z, if the birefringent transparent substrate 42 is not adhered. The distance z is represented by the following numerical equation 6.

[Numerical Equation 6]

z=d−{Δx₁+(f₁−f₀)} (6)

Next, when the birefringent transparent substrate 42 is adhered, a distance from the outermost surface of the birefringent transparent substrate 42 to the light beams passing through near the end of the lens is defined as z′, and a difference between z and z′ is defined as Δz. In this case, the difference Δz is represented by the following numerical equation 7.

[Numerical Equation 7]

Δz=z*Tan θ₁/Tan θ₂−z (7)

In this case, the vertical aberration Δx₂ is represented by the following numerical equation (8).

[Numerical Equation 8]

Δx₂=Δx₁+(f₁−f₀)−Δz (8)

In addition, the Snell laws are applied to derive the numerical equations (9) and (10).

[Numerical Equation 9]

Sin θ₃=n*Sin θ₄ (9)

[Numerical Equation 10]

Sin θ₁=n*Sin θ₂ (10)

The n in the equations (9) and (10) represents the refractive index of the birefringent transparent substrate 42.

As described above, the birefringent transparent substrate 42 has birefringence and has the high refractive index nₑ in the vertical direction. In this case, as shown in FIG. 8, the vertical components of the p-wave polarized light (polarized light in the direction parallel to the incident surface) of the light beams passing through near the end of the lens are greatly refracted being influenced by the refractive index nₑ according to the Snell laws. In contrast, the horizontal components of the p-wave polarized light are refracted being influenced by the refractive index nₒ. As a result, a synthesized wave of the vertical components and the horizontal components of the p-wave polarized light proceed as greatly refracted light beams as compared to a non-birefringent transparent substrate.

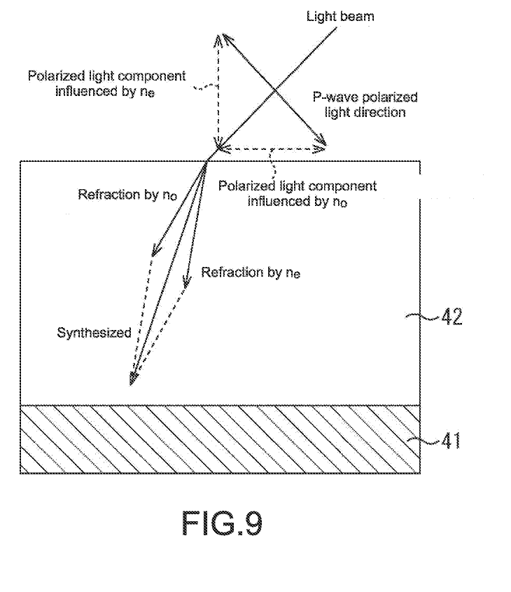

FIG. 9 is an enlarged view of a part of the birefringent transparent substrate 42 encircled by a dotted line shown in FIG. 8.

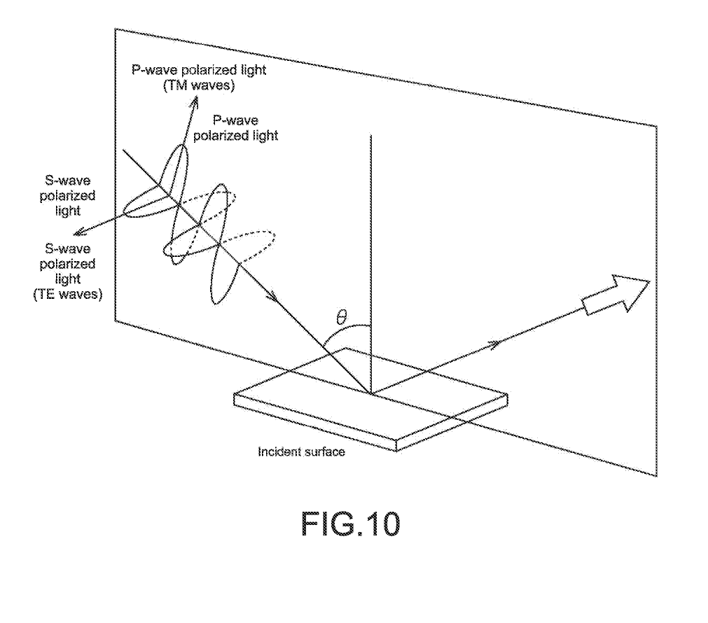

FIG. 10 is a view for illustrating a relationship between the incident surface and the polarized direction. As shown in FIG. 10, a polarized light in a direction parallel to the incident surface is referred to as the p-wave polarized light, an s polarized light in a direction vertical to the incident surface is referred to as the s-wave polarized light.

FIG. 9 shows the synthesized wave of the vertical components of the p-wave polarized light refracted being influenced by the refractive index nₑ and the horizontal components of the p-wave polarized light refracted being influenced by the refractive index nₒ. As shown in FIG. 9, the synthesized wave proceeds as greatly refracted light beams as compared to the non-birefringent transparent substrate.

In other words, because the birefringent transparent substrate 42 has birefringence, the nearer the incident angle of the light beams is to 90 degrees, the greater the light beams are refracted; the nearer the incident angle of the light beams is to zero degree, the smaller the light beams are refracted. For example, the difference between θ₂ and θ₄ becomes smaller than the difference between θ₃ and θ₁ in FIG. 7.

As a result, the focal length becomes long when the light beam passing through the end of the lens pass through the non-birefringent transparent substrate 42 as compared to the case that the light beam passes through the non-birefringent transparent substrate, thereby decreasing the aberration. In FIG. 8, the light beam passing through the birefringent transparent substrate 42 is drawn by the solid line, and the light beam passing through the non-birefringent transparent substrate is drawn by the dotted line. The non-birefringent transparent substrate has the refractive index nₒ both in the vertical and horizontal directions.

Referring to FIGS. 8 and 9, the refraction of the light beams of the p-wave polarized light is described in detail. This is because in the light beams passing through the imaging lens system, the p-wave polarized light is dominant. In other words, an incident angle dependency of a reflectance of the p-wave polarized light differs from that of the s-wave polarized light.

The light passing through near the end of the lens 31 is incident obliquely on the lens surface. The s-wave polarized light (the polarized light in the direction vertical to the incident surface) has a higher reflectance as the incident angle is increased. The p-wave polarized light has a lower reflectance up to the Brewster's angle as the incident angle is increased. As a result, a transmittance will be increased.

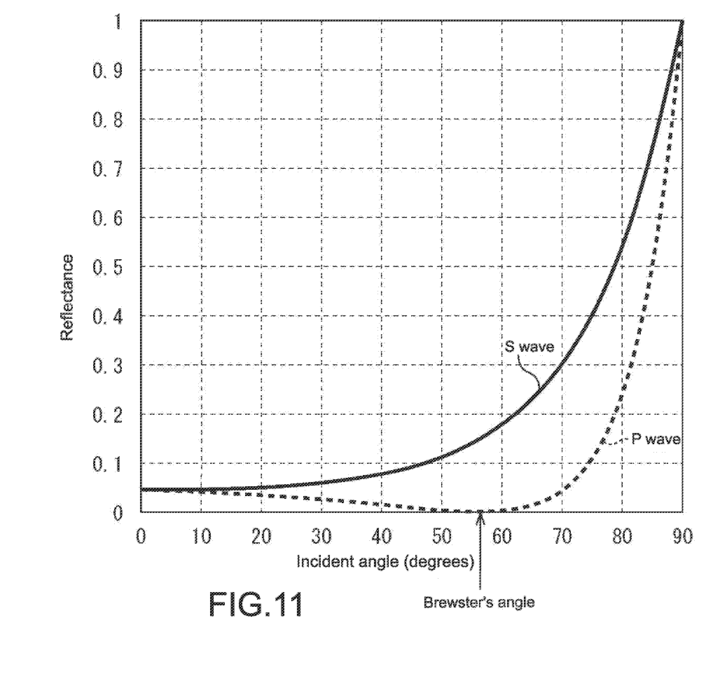

FIG. 11 is a graph showing the incident angle dependency of the light reflectances of the p-wave polarized light and the s-wave polarized light. In FIG. 11, a horizontal axis represents the incident angle, and a vertical axis represents the reflectance. FIG. 11 shows a change in the reflectances of the p-wave polarized light and the s-wave polarized light. As shown in FIG. 11, the p-wave polarized light has a lower reflectance up to the Brewster's angle as the incident angle is increased. In contrast, the s-wave polarized light has a higher reflectance as the incident angle is increased.

Referring to FIG. 6, the imaging lens system is configured only of the lens 31. In fact, the imaging lens system is generally configured of a number of lenses. When the light beams pass through a number of lenses of the imaging lens system, the s-wave polarized light is weaken by generating reflection losses repeatedly but the p-wave polarized light has a great light transmittance. The p-wave polarized light becomes dominant and reaches the light receiving surface of the sensor chip 41.

Accordingly, in the case of the light beams each having a great incident angle and passing through the end of the lens, the refraction of the light beams of the p-wave polarized light should be taken into consideration.

The above-described effect of the birefringence is changed by the F value of the camera. A numerical aperture (NA) of the lens can be represented by NA=Sin θ₁. Furthermore, NH=1/(2*F value). Thus, the incident angle θ₁ is changed by the F value.

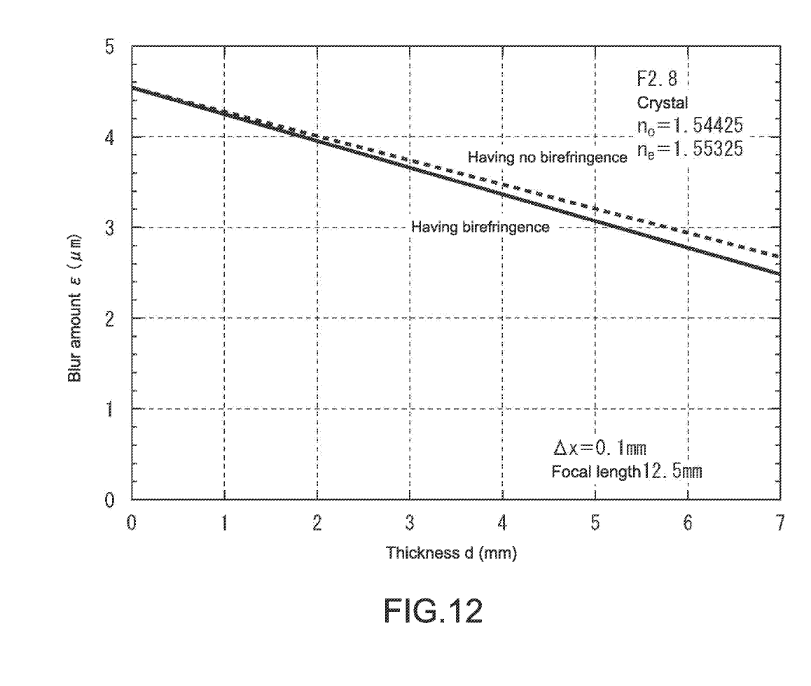

FIG. 12 is a graph showing the effect of the birefringence. In FIG. 12, the horizontal axis represents a thickness of the substrate, and the vertical axis represents the blur amount. The transparent substrates were formed using materials having the birefringence and having no birefringence. The blur amounts were measured depending on the thickness of the substrate.

The transparent substrate (a crystal substrate is supposed) formed of the material having the birefringence has the refractive index nₑ of 1.55325 and the refractive index nₒ of 1.54425. The transparent substrate (a SiO₂ polycrystal substrate or an amorphous substrate is supposed) formed of the material having no birefringence has the refractive index nₒ. The vertical aberration Δx of the lens is 0.1 mm, the F value is 2.8 and the focal length f₀ of the lens in air is 12.5 mm.

As shown in FIG. 12, the blur amount of the transparent substrate (having birefringence) is lower than that of the transparent substrate (having no birefringence). It can be thus concluded that the birefringence of the transparent substrate decreases the resolving power, thereby improving the resolution.

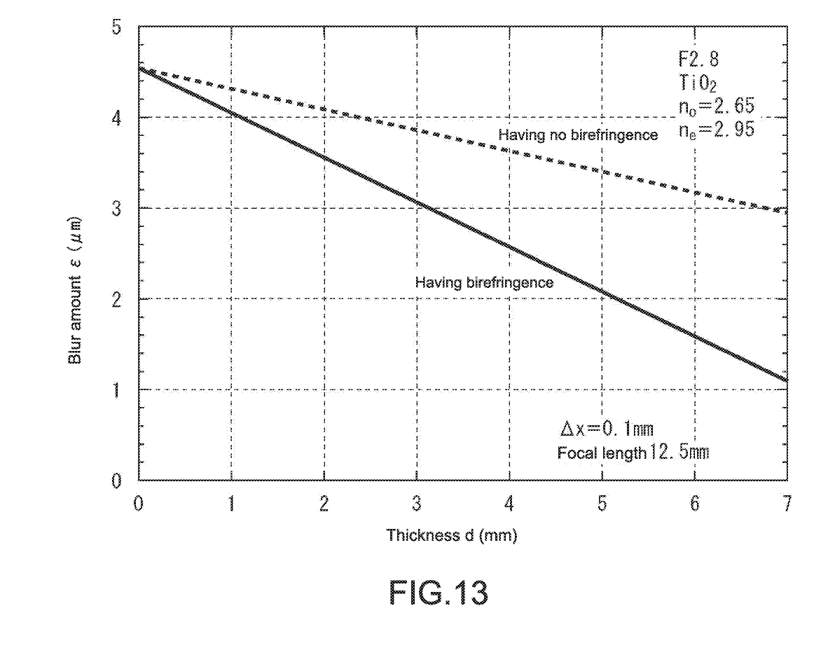

FIG. 13 is another graph showing the effect of birefringence. In FIG. 13, similar to FIG. 12, the horizontal axis represents the thickness of the substrate, and the vertical axis represents the blur amount. The transparent substrates were formed using materials having the birefringence and having no birefringence. The blur amounts were measured depending on the thickness of the substrate.

The transparent substrate (a TiO₂ substrate is supposed) formed of the material having the birefringence in FIG. 13 has the refractive index nₑ of 2.95 and the refractive index nₒ of 2.65. The transparent substrate formed of the material having no birefringence has the refractive index nₒ. The vertical aberration Δx of the lens is 0.1 mm, the F value is 2.8 and the focal length fₒ of the lens in air is 12.5 mm.

As shown in FIG. 13, the blur amount of the transparent substrate (having birefringence) is further decreased.

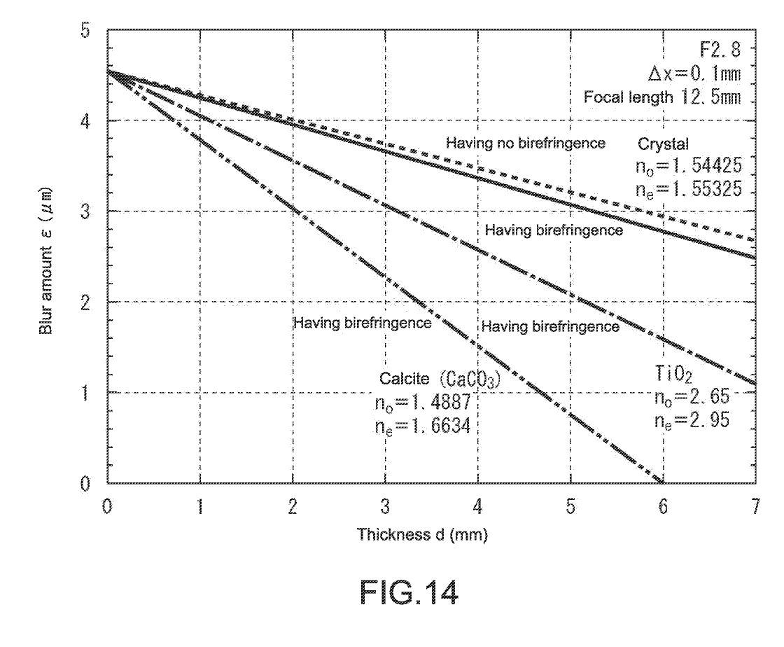

FIG. 14 is still another graph showing the effect of birefringence. In FIG. 14, similar to FIG. 12, the horizontal axis represents the thickness of the substrate, and the vertical axis represents the blur amount. The transparent substrates were formed using materials having the birefringence and having no birefringence. The blur amounts were measured depending on the thickness of the substrate.

The transparent substrate formed of the material having the birefringence in FIG. 14 is supposed to be a crystal, TiO₂ or calcite substrate. The transparent substrate formed of the material having no birefringence is supposed to be a SiO₂ polycrystal or an amorphous substrate. The calcite substrate has the refractive index nₑ of 1.6634 and the refractive index nₒ of 1.4887.

The refractive index ratio nₑ/nₒ of the transparent crystal substrate is 1.0058. The refractive index ratio nₑ/nₒ of the transparent TiO₂ substrate is 1.1132. The refractive index ratio nₑ/nₒ of the transparent calcite substrate is 1.1735. As shown in FIG. 14, the blur amount of the calcite substrate is significantly decreased. It can be therefore concluded that the greater the refractive index ratio nₑ/nₒ is, the smaller the resolving power is due to the birefringence of the transparent substrate and the more the resolution is improved.

For practical purposes, when the transparent substrate is used in the camera or the like, the material of the transparent substrate that is expected to provide the above-described effect by the birefringence desirably has the refractive index ratio nₑ/nₒ of 1.1 or more.

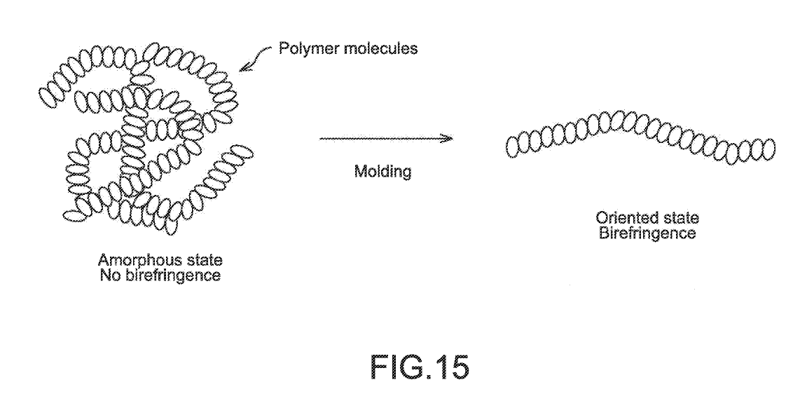

Also, some of high molecular (polymer) or low molecular organic materials have the birefringence. The birefringent transparent substrate 42 shown in FIG. 4 may be configured of the high molecular or low molecular organic materials. FIG. 15 is a schematic view for illustrating a mechanism of a birefringence expression of the polymer.

The polymer includes nanosized molecules in a string shape. In an entirely random state (an amorphous state), the polymer molecules are bent in a coil shape. The polymer molecules in the amorphous state have no directionality and become therefore an entirely uniform medium to light.

When a melt extrusion method or a drawing method is applied to the polymer molecules in the amorphous state, the polymer molecules are oriented. In an oriented state, a refractive index nₚ to a straight line polarized light polarized in an oriented direction (a horizontal direction in FIG. 15) is different from a refractive index nᵥ to a straight line polarized light polarized in a direction orthogonal to the oriented direction (a vertical direction in FIG. 15).

Thus, a magnitude of the birefringence where the refractive indices are different depending on polarized surfaces is represented by Δn (=nₚ−nᵥ). When the Δn is positive, it is called a positive birefringence. When the Δn is negative, it is called a negative birefringence. The polymer types determine the polarity, i.e., positive or negative, of the birefringence.

It is known that the Δn of styrene or PMMA polymer easily becomes negative.

Similar to the high molecular materials, the birefringence is expressed even in the low molecular materials by improving the orientation.

Accordingly, when the birefringent transparent substrate 42 is formed of the high molecular or low molecular organic materials, the molecules may be arranged in a direction vertical to the transparent substrate if the Δn is positive, or the molecules may be arranged in a direction parallel to the transparent substrate if the Δn is negative. By arranging the molecules in this way, the transparent substrate composed of the high molecule or low molecule organic materials will have birefringence having the high refractive index in the vertical direction.

The above-described birefringent transparent substrate 42 has the birefringence attributable to the physical properties of the materials. However, the birefringence may be generated by introducing a specific structure into the transparent substrate even if the material has no birefringence. For example, when the dielectric multilayer structure including materials having different relative permittivities is used, the transparent substrate having the birefringence can be formed even if the material has no birefringence.

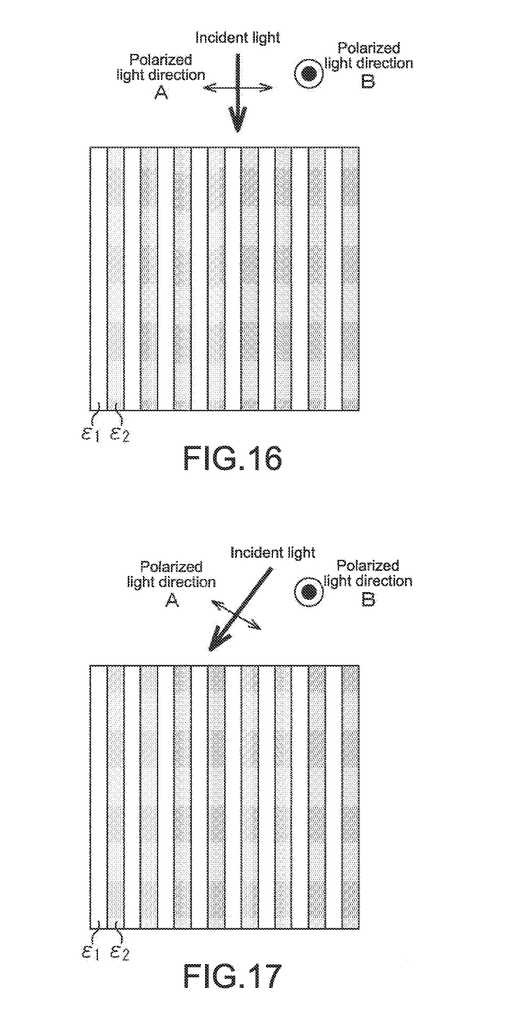

FIG. 16 is a view for illustrating a dielectric multilayer structure using materials having relative permittivity ∈₁ and relative permittivity ∈₂. In FIG. 16, white rectangles of rectangles longer in the vertical direction represent the material having permittivity ∈₁ and the rests thereof, i.e., hatched rectangles represent the material having permittivity ∈₂. In this embodiment shown in FIG. 16, the materials having relative permittivity ∈₁ and relative permittivity ∈₂ shown as the rectangles longer in the vertical direction are disposed in parallel to a light incident direction and the two materials are arranged alternately in a horizontal direction, whereby the dielectric multilayer structure is formed.

The materials having relative permittivity ∈₁ and relative permittivity ∈₂ shown in FIG. 16 may be formed in square column shapes, round column shapes, or other shapes, for example.

The light is incident from top to bottom in FIG. 16. A polarized light in right and left directions in FIG. 16 is denoted as “A”. A polarized light in a depth direction in FIG. 16 is denoted as “B”. The average relative permittivities ∈₁ and ∈₂ are represented by the following numerical equations (11) and (12).

$$\begin{matrix}[ Numerical Equation 11 ] & \\ {ɛ}_{A} = f \times {ɛ}_{1} + ( 1 - f ) \times {ɛ}_{2} & ( 11 ) \\ [ Numerical Equation 12 ] & \\ \frac{1}{{ɛ}_{B}} = \frac{f}{{ɛ}_{1}} + \frac{1 - f}{{ɛ}_{2}} & ( 12 )\end{matrix}$$

In the numerical equations (11) and (12), f denotes volume occupation of the material having the relative permittivity ∈₁.

The refractive index of the light is a square root of the relative permittivity. Accordingly, the dielectric multilayer structure having f=0.5 is formed using the materials having the refractive index of 1.4 (∈₁=1.96) and the refractive index of 2.0 (∈₂=4.0), ∈_{A}=2.98 and ∈_{B}=2.63. In this case, the polarized light A in the right and left directions in FIG. 16 has the refractive index n_{A} of 1.73, and the polarized light B in the depth direction has the refractive index n_{B} of 1.26, thereby providing the effect of the birefringence.

Air can be used for the material having the low refractive index material (the material having the relative permittivity ∈₁). In this case, the difference between the refractive indices is greater, which is effective.

The embodiment shown in FIG. 16 is based on the premise that the light is incident in parallel to the vertical direction of the material configuring the dielectric multilayer structure. For example as shown in FIG. 17, the effect of the birefringence can be provided by the dielectric multilayer structure even when the light is obliquely incident.

In FIG. 17, white rectangles longer in the vertical direction represent the material having permittivity ∈₁ and the rests thereof, i.e., hatched rectangles represent the material having permittivity ∈₂. In FIG. 17, similar to FIG. 16, the materials having relative permittivity ∈₁ and relative permittivity ∈₂ shown as the rectangles longer in the vertical direction are disposed in parallel to a light incident direction and the two materials are arranged alternately in a horizontal direction, whereby the dielectric multilayer structure is formed.

In FIG. 17, unlike FIG. 16, the light is incident obliquely from upper right to lower left in FIG. 17. A polarized light in a lower left and upper right direction in FIG. 17 is denoted as “A”. A polarized light in a depth direction in FIG. 17 is denoted as “B”.

Although a magnitude relationship between the refractive indices of the lights A and B in FIG. 17 (n_{A}>n_{E}) is opposite to that in FIG. 16, the effect of the birefringence can be provided by the dielectric multilayer structure.

As described above referring to FIG. 17, the effect of the birefringence can be provided by the dielectric multilayer structure even when the light is obliquely incident. In this way, a variety of structures can be available.

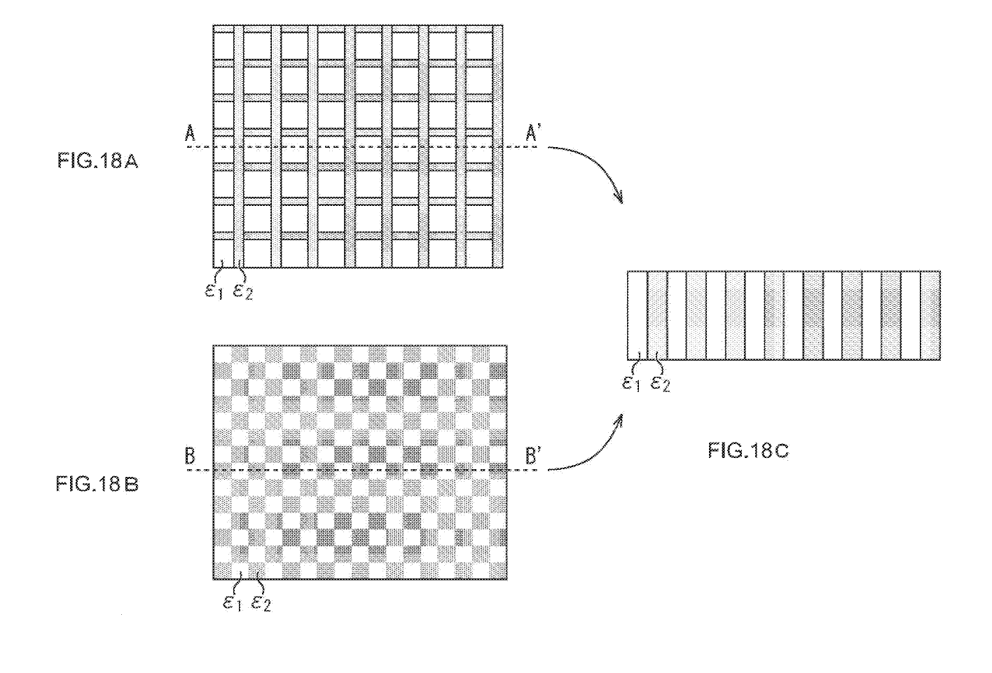

FIGS. 18A, 18B and 18C show examples of the dielectric multilayer structure. FIGS. 18A and 18B are top views of the dielectric multilayer structure. FIG. 18C is a sectional view along an A-A′ line of FIG. 18A or a B-B′ line of FIG. 18B. In FIGS. 18A to 18c, white sections represent the material having permittivity ∈₁ and the hatched sections represent the material having permittivity ∈₂.

FIG. 18A is a front view of the dielectric multilayer structure where the material having permittivity ∈₂ is arranged in a grid (square) shape. The material having permittivity ∈₁ may be arranged in a lattice shape. Here, the arrangement example is in a lattice shape, but may be in a hexagon or octagon shape.

FIG. 18B is a front view of the dielectric multilayer structure where the material having permittivity ∈₂ (or the material having permittivity ∈₁) is arranged in a lattice shape. Here, the arrangement example is in a lattice shape, but may be in a circle shape.

FIG. 18C is a sectional view of FIG. 18A or FIG. 18B where the material having permittivity ∈₂ and material having permittivity ∈₁ are arranged alternately in a horizontal direction.

In order to provide the birefringence in the dielectric multilayer structure shown in FIGS. 18A to 18C, a structural pattern should have the same size as or smaller than a wavelength. For example, the structural pattern should have a width of 500 nm or less in a visible light region. In other words, in the dielectric multilayer structure, the sections having the same specific dielectric should be 500 nm or less. In addition, a cyclic pattern may be desirable because no distribution is generated at in-plane of the dielectric multilayer structure.

The birefringent transparent substrate 42 in the image sensor 40 to which the present technology is applied may be formed of the above-described dielectric multilayer structure shown in FIGS. 16 to 18.

As thus far described, by using the birefringent transparent substrate 42, the spherical aberration of the imaging lens system is improved, thereby providing a small pixel size and resolution improvement. Also, the chromatic aberration of the imaging lens system is improved, thereby providing a small pixel size and resolution improvement.

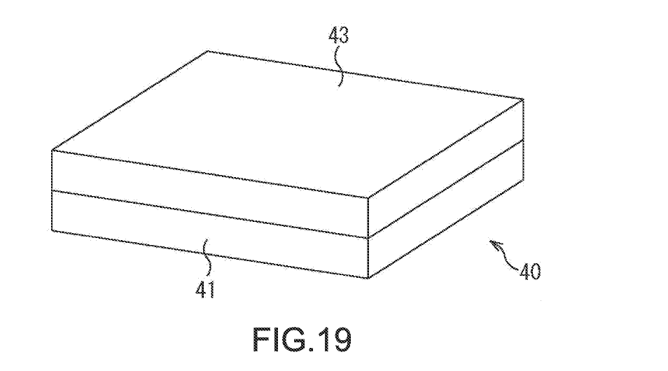

FIG. 19 is a perspective view showing a solid state imaging apparatus (an image sensor) according to another embodiment of the present technology. An image sensor 40 shown in FIG. 19 has a configuration that a transparent substrate having refractive index dispersion 43 is disposed on the light receiving surface of the sensor chip 41.

Herein, the refractive index dispersion represents a property having different refractive indices corresponding to light beam directions transmitting a member.

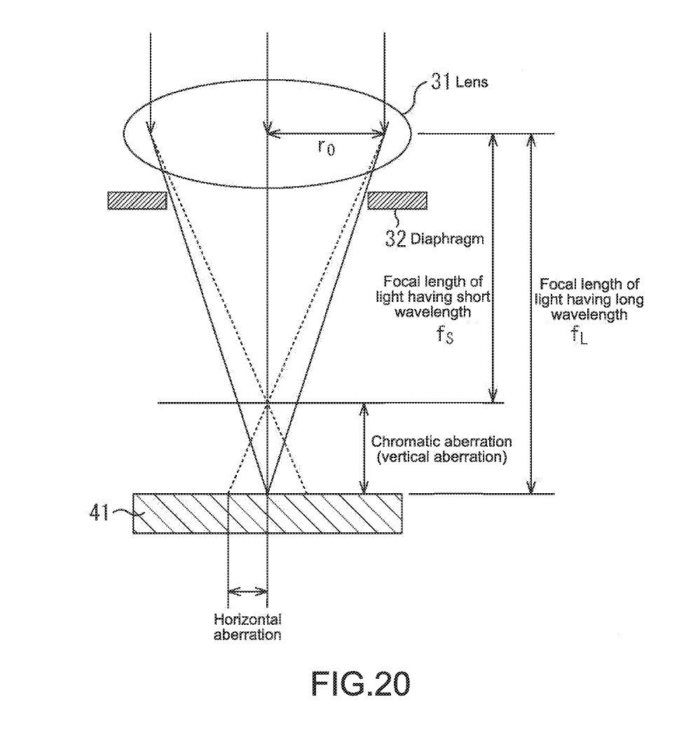

FIG. 20 is a view for illustrating the chromatic aberration of the imaging lens system.

In FIG. 20, the lens 31 corresponds to the imaging lens system. The light collected by the lens 31 reach the light receiving surface of the sensor chip 41 via a diaphragm 32. Herein, no transparent substrate having refractive index dispersion 43 is disposed.

In FIG. 20, a light axis is represented by a straight line passing through a center of the lens 31 and reaching a nearly center of the light receiving surface of the sensor chip 41.

The chromatic aberration is a phenomenon that occurs when the material of the lens 31 has a chromatic dispersion property. As the light having a short wavelength has a high refractive index, a focal length f_{S} of the lens 31 becomes short. In contrast, as the light having a long wavelength has a low refractive index, a focal length f_{L} of the lens 31 becomes long. In this way, the chromatic aberration is generated.

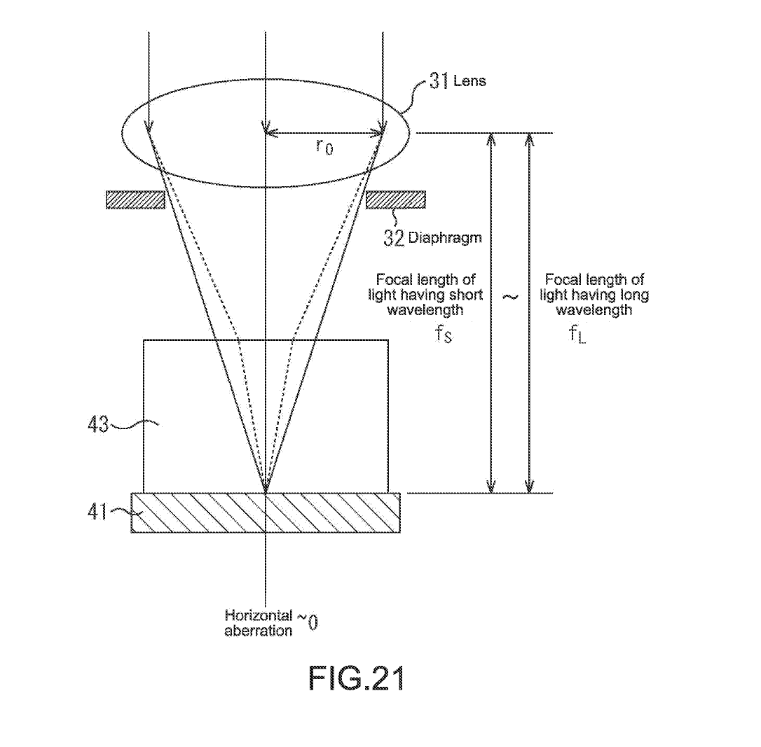

FIG. 21 is a view for illustrating a change of the chromatic aberration of the imaging lens system by disposing the transparent substrate having refractive index dispersion 43. As shown in FIG. 21, the transparent substrate having refractive index dispersion 43 is disposed on the light receiving surface of the sensor chip 41.

The transparent substrate having refractive index dispersion 43 is configured to greatly refract the light having a short wavelength and to slightly refract the light having a long wavelength. In FIG. 21, as the transparent substrate having refractive index dispersion 43 is disposed, the focal length f_{S} of the light having a short wavelength continues to be longer, but the focal length f_{L} of the light having a long wavelength becomes little longer. Thus, both of the vertical aberration and the horizontal aberration are nearly zero, and the chromatic aberration is improved.

In this way, by disposing the transparent substrate having refractive index dispersion 43, the chromatic aberration is improved, thereby providing a small pixel size and resolution improvement.

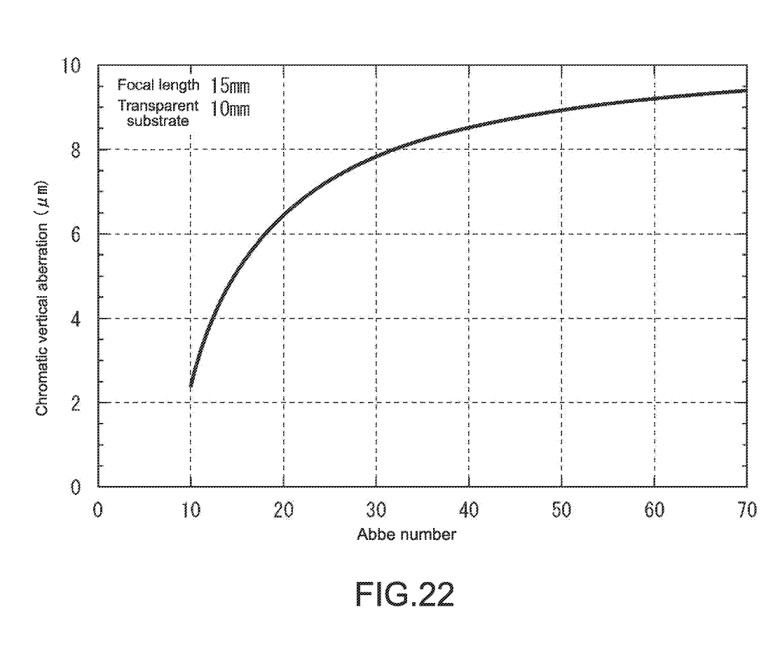

FIG. 22 is a graph showing a relationship between the chromatic aberration and an Abbe number that is an index showing the chromatic dispersion property of the material of the transparent substrate having refractive index dispersion 43. In FIG. 22, a horizontal axis represents the Abbe number of the transparent substrate having refractive index dispersion 43, a vertical axis represents the chromatic aberration (the horizontal aberration) on the light receiving surface of the sensor chip 41, and a change in the chromatic aberration corresponding to the Abbe number is shown. Herein, the focal length in air of the lens 31 is 15 mm, and the thickness of the transparent substrate having refractive index dispersion 43 is 10 mm.

The Abbe number ν_{d} is represented by the numerical equation (13).

$$\begin{matrix}[ Numerical Equation 13 ] & \\ {v}_{d} = \frac{{n}_{d} - 1}{{n}_{F} - {n}_{c}} & ( 13 )\end{matrix}$$

The Abbe number is determined by the wavelengths of the dark lines on the spectra specific to the respective elements, which are called as Fraunhofer lines.

In the numerical equation (13), n_{d}, n_{F} and n_{c} represent the refractive indices at wavelengths 587.56 nm (element He), 486.13 nm (element H) and 656.27 nm (element H), respectively. According to the numerical equation (13), the smaller the Abbe number ν_{d} is, the greater the chromatic dispersion property of the refractive index is.

As shown in FIG. 22, it can be found that the smaller the Abbe number is, the smaller the chromatic aberration is. Especially when the Abbe number is 40 or less, the chromatic aberration is significantly decreased.

The aberration can be decreased by simply using the transparent substrate having the chromatic dispersion property (the Abbe number ν_{d} is small). If the transparent substrate having the chromatic dispersion property is used in combination with the birefringent substrate, the aberration can be further decreased, thereby significantly improving the resolution.

In this way, by forming the transparent substrate having refractive index dispersion 43 using the material having the Abbe number of 40 or less, the chromatic aberration can be significantly improved.

As the material of the transparent substrate having refractive index dispersion 43, the organic material such as PC, PS, AS resin and MS resin or the inorganic material such as the glass-based material and an oxide, e.g., TiO₂ can be used.

Both of the transparent substrate having refractive index dispersion 43 and the birefringent transparent substrate 42 may be used in combination. In this way, the chromatic aberration is improved as well as the spherical aberration, thereby providing a smaller pixel size and resolution improvement.

Next, a production method of the image sensor 40 as described above referring to FIG. 4 will be described. Firstly, a production method of the image sensor 40 will be described by forming the birefringent transparent substrate 42 using the inorganic material having birefringence.

On a part of a space between the imaging lens system and the sensor chip 41 of the image sensor 40 directly above the light receiving surface of the sensor chip 41, the birefringent transparent substrate 42 composed of the material having the refractive index (n>1) higher than air (the refractive index of 1) and the birefringence is disposed.

When the birefringent transparent substrate 42 is disposed on the light receiving surface of the sensor chip 41, a direction having the high refractive index nₑ is adjusted to be vertical to the light receiving surface and a direction having the low refractive index nₒ is adjusted to be parallel to the light receiving surface.

There is an empty space from the surface of the birefringent transparent substrate 42 to the imaging lens system (the lens 31) and the diaphragm 32.

For the birefringent transparent substrate 42, a material having high transmittance to the light within a wavelength band to be received and detected, desirably a transparent material, is used.

As the material of the birefringent transparent substrate 42, the inorganic material such as an oxide of crystal (SiO₂), TiO₂, calcite (CaCO₃) or lithium niobate is used. When TiO₂ is used among the above-described inorganic materials, the Abbe number will be 8.3 (<40) by the chromatic dispersion property of the refractive index, thereby decreasing the chromatic aberration at the same time. By forming the birefringent transparent substrate 42 using TiO₂, the resolution is remarkably improved.

The birefringent transparent substrate 42 has a thickness of 1 mm or more, desirably 3 mm. As described above referring to FIGS. 12 to 14, this allows that the blur amount is decreased, the resolving power is lowered and the resolution is improved.

When the birefringent transparent substrate 42 is disposed on the light receiving surface of the sensor chip 41, a resin type adhesive agent may be used to adhere the birefringent transparent substrate 42 to the light receiving surface of the sensor chip 41 or annealing, e.g., laser annealing, may be used to increase a bond force between the birefringent transparent substrate 42 and the light receiving surface of the sensor chip 41 and bond them.

In this way, the image sensor 40 is produced.

Next, a production method of the image sensor 40 as described above referring to FIG. 4 will be described by forming the birefringent transparent substrate 42 using the organic material having birefringence.

On a part of a space between the imaging lens system and the sensor chip 41 of the image sensor 40 directly above the light receiving surface of the sensor chip 41, the birefringent transparent substrate 42 composed of the material having the refractive index (n>1) higher than air (the refractive index of 1) and the birefringence is disposed.

When the birefringent transparent substrate 42 is disposed on the light receiving surface of the sensor chip 41, a direction having the high refractive index nₑ is adjusted to be vertical to the light receiving surface and a direction having the low refractive index nₒ is adjusted to be parallel to the light receiving surface.

There is an empty space from the surface of the birefringent transparent substrate 42 to the imaging lens system (the lens 31) and the diaphragm 32.

For the birefringent transparent substrate 42, a material having high transmittance to the light within a wavelength band to be received and detected, desirably a transparent material, is used.

As the material of the birefringent transparent substrate 42, the organic material such as polymethyl methacrylate (PMMA), polycarbonate resin (PC), polystyrene (PS), acrylonitrile styrene (AS resin) and polymethacrylic styrene (MS resin) is used.

The birefringent transparent substrate 42 has a thickness of 1 mm or more, desirably 3 mm. As described above referring to FIGS. 12 to 14, this allows that the blur amount is decreased, the resolving power is lowered and the resolution is improved.

When the birefringent transparent substrate 42 is disposed on the light receiving surface of the sensor chip 41, a resin type adhesive agent may be used to adhere the birefringent transparent substrate 42 to the light receiving surface of the sensor chip 41 or annealing, e.g., laser annealing, may be used to increase a bond force between the birefringent transparent substrate 42 and the light receiving surface of the sensor chip 41 and bond them.

When the birefringent transparent substrate 42 is formed, a melt extrusion method or a drawing method may be used to increase the orientation of molecules, thereby improving the birefringence. Thus, the birefringence of polymethyl methacrylate (PMMA) or polycarbonate resin (PC) may be increased.

As the Δn of PMMA, PS, AS resin or MS resin easily becomes negative, the orientation of the molecules may be desirably parallel to the birefringent transparent substrate 42. In other words, the birefringent transparent substrate 42 may be produced by the melt extrusion method or the drawing method such that a stress is applied to the direction parallel to the birefringent transparent substrate 42.

PC has the Abbe number of 30 (<40), PS has the Abbe number of 31 (<40), AS resin has the Abbe number of 35 (<40) and MS resin has the Abbe number of 35 (<40). These materials can be used to improve the chromatic aberration. Thus, the birefringent transparent substrate 42 is formed by using PC, PS, AS resin or MS resin, thereby remarkably improving the resolution.

In this way, the image sensor 40 is produced. Next, a production method of the image sensor 40 as described above referring to FIG. 4 by forming the birefringent transparent substrate 42 using the dielectric multilayer structure.

On a part of a space between the imaging lens system and the sensor chip 41 of the image sensor 40 directly above the light receiving surface of the sensor chip 41, the birefringent transparent substrate 42 composed of the material having the refractive index (n>1) higher than air (the refractive index of 1) and the birefringence is disposed.

When the birefringent transparent substrate 42 is disposed on the light receiving surface of the sensor chip 41, a direction having the high refractive index nₑ is adjusted to be vertical to the light receiving surface and a direction having the low refractive index nₒ is adjusted to be parallel to the light receiving surface.

There is an empty space from the surface of the birefringent transparent substrate 42 to the imaging lens system (the lens 31) and the diaphragm 32.

For the birefringent transparent substrate 42, a material having high transmittance to the light within a wavelength band to be received and detected, desirably a transparent material, is used.

The birefringent transparent substrate 42 is formed by using the dielectric multilayer structure as described above referring to FIG. 16. In other words, the material having relative permittivity ∈₁ (the low refractive index material) and the material having relative permittivity ∈₂ (the high refractive index material) are arranged alternately, whereby the dielectric multilayer structure is formed.

When the birefringent transparent substrate 42 is disposed on the light receiving surface of the sensor chip 41, a resin type adhesive agent may be used to adhere the birefringent transparent substrate 42 to the light receiving surface of the sensor chip 41 or annealing, e.g., laser annealing, may be used to increase a bond force between the birefringent transparent substrate 42 and the light receiving surface of the sensor chip 41 and bond them.

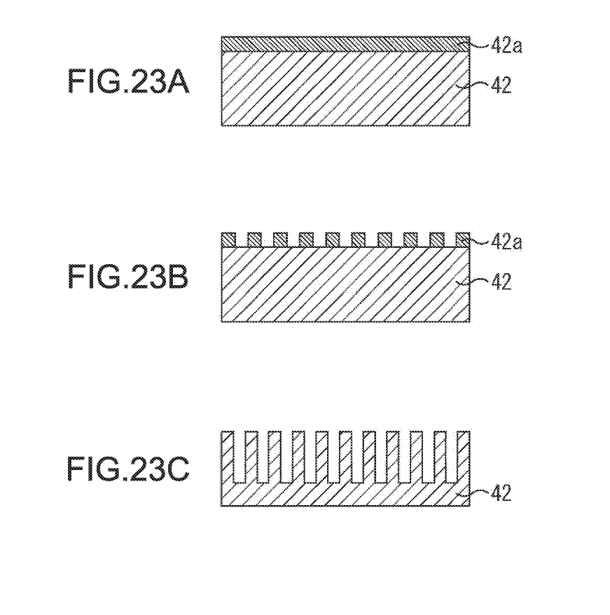

FIGS. 23A-C show a manufacturing process of forming the birefringent transparent substrate using the dielectric multilayer structure. As the low refractive index material (the material having relative permittivity ∈₁), air is used here.

Firstly, as shown in FIG. 23A, a resist 42a is applied over a main material (the high refractive index material) of the birefringent transparent substrate 42.

The resist 42a is partially exposed using a resist mask and developed to form a desired resist pattern. In this way, the resist 42a is partially removed and a comb-shaped resist pattern is formed.

A width of the mask is desirably less than a wavelength order (500 nm or less) because the birefringence is developed against visible light, but is not especially specified as long as the width is smaller than a wavelength size. Thus, in the resist pattern as shown in FIG. 23B, for example, the resist mask should be produced such that each space between convex parts of the resist is 500 nm or less.

Although the exposure lithography is used here, an electron beam lithography patterning etc. may be used.

Next, the resist pattern shown in FIG. 23B is partially etched to form the dielectric multilayer structure. Etching may be dry etching such as RIE or chemical etching such as wet etching.

In this way, the birefringent transparent substrate 42 using the dielectric multilayer structure shown in FIG. 23C is formed. In FIG. 23C, air exists at white sections by removing the high refractive index material with etching. Alternatively, the low refractive index material may be buried into the white sections.

Alternatively, the birefringent transparent substrate 42 using the dielectric multilayer structure may be formed using a mold.

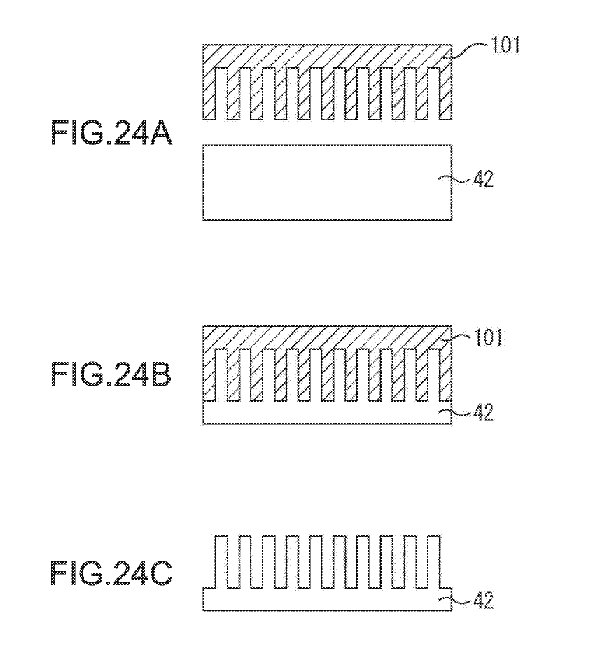

FIGS. 24A-C show another manufacturing process of forming the birefringent transparent substrate 42 using the dielectric multilayer structure. As the low refractive index material (the material having relative permittivity ∈₁), air is used here.

Firstly, as shown in FIG. 24A, a mold for molding a main material (the high refractive index material) is prepared. FIG. 24A shows the birefringent transparent substrate 42 before molding, i.e., a plate-like transparent substrate formed of the high refractive index material, and a comb-shaped mold 101. The mold 101 is formed not always of a metal, but of a semiconductor such as silicon.

Next, as shown in FIG. 24B, the transparent substrate formed of the high refractive index material is molded using the mold 101. In this case, the mold 101 is heated to press the transparent substrate formed of the high refractive index material (the birefringent transparent substrate 42 before molding).

Then, the mold 101 is cooled and released from the transparent substrate formed of the high refractive index material. Thus, as shown in FIG. 24C, the transparent substrate formed of the high refractive index material is molded to have a comb shape to provide the birefringent transparent substrate 42.

When the birefringent transparent substrate 42 using the dielectric multilayer structure is formed with the mold, it is possible to form a large quantity of the structural substrate having the same shape in a press working, once the mold 101 is produced. Thus, a mass production is available with low costs.

The birefringent transparent substrate 42 has a thickness of 1 mm or more, desirably 3 mm. As described above referring to FIGS. 12 to 14, this allows that the blur amount is decreased, the resolving power is lowered and the resolution is improved.

In this way, the image sensor 40 is produced.

Next, a production method of the image sensor 40 as described above referring to FIG. 19 will be described.

On a part of a space between the imaging lens system and the sensor chip 41 of the image sensor 40 directly above the light receiving surface of the sensor chip 41, the transparent substrate having refractive index dispersion 43 having the refractive index (n>1) higher than air (the refractive index of 1) and the birefringence is disposed.

There is an empty space from the surface of the transparent substrate having refractive index dispersion 43 to the imaging lens system (the lens 31) and the diaphragm 32.

For the transparent substrate having refractive index dispersion 43, a material having high transmittance to the light within a wavelength band to be received and detected, desirably a transparent material, is used.

As the material of the transparent substrate having refractive index dispersion 43, the material such as PC, PS, AS resin and MS resin can be used. Also, the glass-based substrate and an oxide, e.g., TiO₂ may be used. As these materials have birefringence, the spherical aberration can be improved in addition to the chromatic aberration.

The material of the transparent substrate having refractive index dispersion 43 has a thickness of 1 mm or more, desirably 3 mm. As described above referring to FIGS. 12 to 14, this allows that the blur amount is decreased, the resolving power is lowered and the resolution is improved.

When the material of the transparent substrate having refractive index dispersion 43 is disposed on the light receiving surface of the sensor chip 41, a resin type adhesive agent may be used to adhere the material of the transparent substrate having refractive index dispersion 43 to the light receiving surface of the sensor chip 41 or annealing, e.g., laser annealing, may be used to increase a bond force between the material of the transparent substrate having refractive index dispersion 43 and the light receiving surface of the sensor chip 41 and bond them.

Desirably, the birefringent material of the material of the transparent substrate having refractive index dispersion 43 has an Abbe number of 40 or less.

Examples of the glass-based material having an Abbe number ν_{d} of 40 or less include the following: S-BAH28 (νd=38), S-TIM 1 (νd=36), S-TIM 2 (νd=36), S-TIM 5 (νd=38), S-TIM 8 (νd=39), S-TIM 22 (νd=34), S-TIM 25 (νd=32), S-TIM 27 (νd=34), S-TIM 28 (νd=31), S-TIM 35 (νd=30), S-TIM 39 (νd=33), S-TIH 4 (νd=28), S-TIH 6 (νd=25), S-TIH 10 (νd=29), S-TIH 11 (νd=26), S-TIH 13 (νd=28), S-TIH 14 (νd=27), S-TIH 18 (νd=29), S-TIH 23 (νd=26), S-TIH 53 (νd=24), S-LAM66 (νd=35), S-LAH60 (νd=37), S-LAH63 (νd=40), S-FTM16 (νd=35), S-NPH 1 (νd=23), BAH32 (νd=39), PBM 3 (νd=37), PBH 1 (νd=30), PBH 3 (νd=28), PBH71 (νd=21), LAM 7 (νd=35), LAH78 (νd=32), BPH 5 (νd=40), BPH 8 (νd=35), PBM 1 (νd=36), PBM 2 (νd=36), PBM 4 (νd=36), BM 5 (νd=38), PBM 6 (νd=35), PBM 8 (νd=39), PBM 9 (νd=38), PBM 22 (νd=34), PBM 25 (νd=32), PBM 27 (νd=35), PBM 28 (νd=31), PBM 35 νd=30), PBM 39 (νd=33), TIM11 (νd=36), PBH 4 (νd=28), PBH 6 (νd=25), PBH 10 (νd=28), PBH11 (νd=26), PBH 13 (νd=28), PBH 14 (νd=27), PBH 21 (νd=21), PBH 23 (νd=26), PBH 25 (νd=27), PBH 53 (νd=24), PBH 72 (νd=21), TPH55 (νd=25), TIH53 (νd=24), BAM21 (νd=39), BAH22 (νd=36), BAH28 (νd=38), BAH30 (νd=39), BAH78 (νd=38), LAH71 (νd=32), S-LAH75 (νd=35), BPH40 (νd=38), BPH45 (νd=34), BPH50 (νd=32).

In this way, the image sensor 40 is produced.

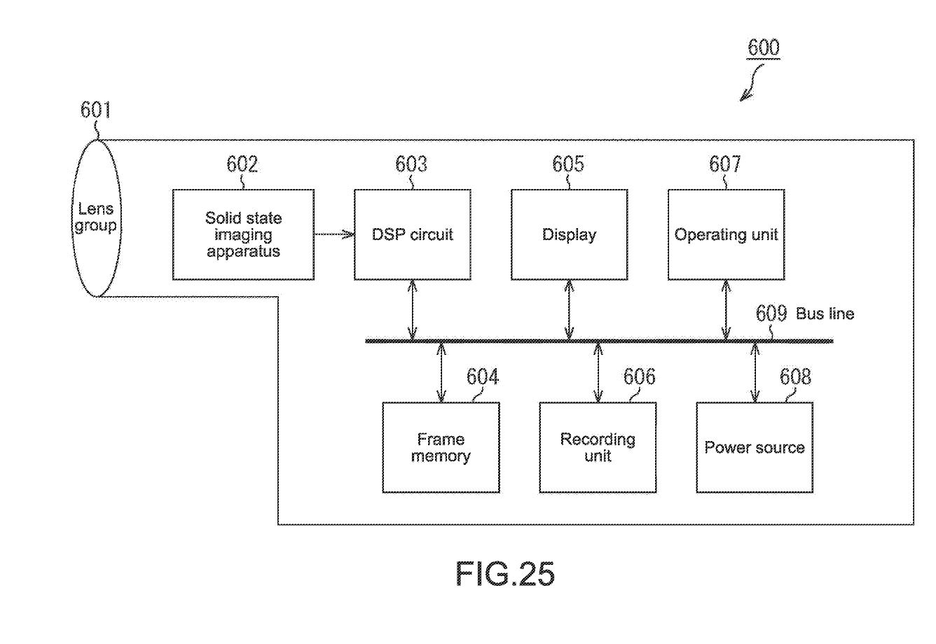

FIG. 25 is a block diagram showing a configuration example of a camera apparatus as an electronic device according to the present technology.

A camera apparatus 600 shown in FIG. 25 includes an optical unit 601 having a group of lenses, a solid state imaging apparatus (an imaging device) 602 to which the above-described configuration of pixels is applied, and a DPS circuit 603 that is a camera signal processing circuit. The camera apparatus 600 also includes a frame memory 604, a display 605, a recording unit 606, an operating unit 607, and a power source 608. The DSP circuit 603, the frame memory 604, the display 605, the recording unit 606, the operating unit 607 and the power source 608 are interconnected via bus lines 609.

The optical unit 601 takes an incident light (an image light) from an object and forms an image on an imaging area of the solid state imaging apparatus 602. The solid state imaging apparatus 602 converts an amount of the incident light imaged on the imaging area by the optical unit 601 into an electrical signal per pixel and outputs the electrical signal as a pixel signal. As the solid state imaging apparatus 602, the solid state imaging apparatus according to the above-described embodiment can be used.

The display 605 is a panel type display device such as a liquid crystal panel, an organic EL (Electro Luminescence) panel and the like, and displays moving images or still images captured by the solid state imaging apparatus 602. The recording unit 606 records the moving images or still images captured by the solid state imaging apparatus 602 to a recording medium such as a video tape, a DVD (Digital Versatile Disk) and the like.

The operating unit 607 issues an operation command of a variety of functions belonging to the camera apparatus 600 by a user's operation. The power source 608 supplies power to the DSP circuit 603, the frame memory 604, the display 605, the recording unit 606 and the operating unit 607 for operation, as appropriate.

The present technology can be applied not only to the image sensor that detects a distribution of the amount of the incident visible light and captures images, but also to general image sensors (physical amount distribution detecting apparatuses) including an image sensor for capturing images of a distribution of the incident amount of infrared rays, X rays, particles or the like, and, in a broad sense, a fingerprint detection sensor that detects other physical amount distributions such as a pressure and a capacitance and captures images.

A series of the above-described processes includes not only the processes that are carried out in time series along the order described herein, but also the process that are carried out in parallel or separately not necessarily in time series.

The embodiments of the present technology are not limited to the embodiments described above, and variations and modifications may be made without departing from the scope of the present technology.

It should be understood by those skilled in the art that various modifications, combinations, sub-combinations and alterations may occur depending on design requirements and other factors insofar as they are within the scope of the appended claims or the equivalents thereof.

The present disclosure may have the following configurations.

(1) A solid state imaging apparatus, including:

a transparent substrate formed of a birefringent material having a high refractive index in a direction vertical to a light receiving surface and a low refractive index in a direction parallel to the light receiving surface, the transparent substrate being disposed on the light receiving surface.

(2) The solid state imaging apparatus according to (1) above, in which

the birefringent material has a refractive index ratio nₑ/nₒ of the high refractive index nₑ and the low refractive index nₒ of 1.1 or more.

(3) The solid state imaging apparatus according to (1) or (2) above, in which

the birefringent material is an inorganic material.

(4) The solid state imaging apparatus according to (3) above, in which

the inorganic material is crystal, TiO₂, calcite or lithium niobate.

(5) The solid state imaging apparatus according to (1) above, in which

the birefringent material is an organic material.

(6) The solid state imaging apparatus according to (5) above, in which

the organic material is polymethyl methacrylate (PMMA), polycarbonate resin (PC), polystyrene (PS), acrylonitrile styrene (AS resin) and polymethacrylic styrene (MS resin).

(7) The solid state imaging apparatus according to (1) or (2) above, in which

the birefringent material has a dielectric multilayer structure where materials having different relative permittivities are combined.

(8) The solid state imaging apparatus according to (7) above, in which

the dielectric multilayer structure is provided by combining the materials having different relative permittivities such that each area of the materials having the same relative permittivity is 500 nm or less.

(9) The solid state imaging apparatus according to (8) above, in which

the dielectric multilayer structure is formed by arranging the materials having the same relative permittivity in a lattice, hexagon, octagon or columnar shape.

(10) The solid state imaging apparatus according to any one of (1) to (9) above, in which

the birefringent material has refractive index dispersion such that the refractive index is high to a light having a short wavelength and the refractive index is low to a light having a long wavelength.

(11) The solid state imaging apparatus according to (10) above, in which

the birefringent material has an Abbe number of 40 or less.

(12) An electronic device, including a transparent substrate formed of a birefringent material having a high refractive index in a direction vertical to a light receiving surface and a low refractive index in a direction parallel to the light receiving surface, the transparent substrate being disposed on the light receiving surface.

(13) A solid state imaging apparatus, including a transparent substrate formed of a material having refractive index dispersion such that the refractive index is high to a light having a short wavelength and the refractive index is low to a light having a long wavelength, the transparent substrate being disposed on the light receiving surface.

(14) The solid state imaging apparatus according to (13) above, in which

the material having refractive index dispersion has an Abbe number of 40 or less.

(15) The solid state imaging apparatus according to (14) above, in which

the material having refractive index dispersion is polycarbonate resin (PC), polystyrene (PS), acrylonitrile styrene (AS resin), polymethacrylic styrene (MS resin), a glass-based material or TiO₂.

(16) An electronic device, including a solid state imaging apparatus including a transparent substrate formed of a material having refractive index dispersion such that the refractive index is high to a light having a short wavelength and the refractive index is low to a light having a long wavelength, the transparent substrate being disposed on the light receiving surface.

According to the third and fourth embodiments of the present technology, the transparent substrate formed of a material having refractive index dispersion such that the refractive index is high to a light having a short wavelength and the refractive index is low to a light having a long wavelength is disposed on the light receiving surface.

What is claimed is:

1. A solid state imaging apparatus, comprising:
a transparent substrate formed of a birefringent material having a high refractive index in a direction vertical to a light receiving surface and a low refractive index in a direction parallel to the light receiving surface, the transparent substrate being disposed on the light receiving surface.

2. The solid state imaging apparatus according to claim 1, wherein
the birefringent material has a refractive index ratio nₑ/nₒ of the high refractive index nₑ and the low refractive index nₒ of 1.1 or more.

3. The solid state imaging apparatus according to claim 1, wherein
the birefringent material is an inorganic material.

4. The solid state imaging apparatus according to claim 3, wherein
the inorganic material is crystal, TiO₂, calcite or lithium niobate.

5. The solid state imaging apparatus according to claim 1, wherein
the birefringent material is an organic material.

6. The solid state imaging apparatus according to claim 5, wherein
the organic material is polymethyl methacrylate (PMMA), polycarbonate resin (PC), polystyrene (PS), acrylonitrile styrene (AS resin) and polymethacrylic styrene (MS resin).

7. The solid state imaging apparatus according to claim 1, wherein
the birefringent material has a dielectric multilayer structure where materials having different relative permittivities are combined.

8. The solid state imaging apparatus according to claim 7, wherein
the dielectric multilayer structure is provided by combining the materials having different relative permittivities such that each area of the materials having the same relative permittivity is 500 nm or less.

9. The solid state imaging apparatus according to claim 8, wherein
the dielectric multilayer structure is formed by arranging the materials having the same relative permittivity in a lattice, hexagon, octagon or columnar shape.

10. The solid state imaging apparatus according to claim 1, wherein
the birefringent material has refractive index dispersion such that the refractive index is high to a light having a short wavelength and the refractive index is low to a light having a long wavelength.

11. The solid state imaging apparatus according to claim 10, wherein
the birefringent material has an Abbe number of 40 or less.

12. An electronic device, comprising a transparent substrate formed of a birefringent material having a high refractive index in a direction vertical to a light receiving surface and a low refractive index in a direction parallel to the light receiving surface, the transparent substrate being disposed on the light receiving surface.

13. A solid state imaging apparatus, comprising a transparent substrate formed of a material having refractive index dispersion such that the refractive index is high to a light having a short wavelength and the refractive index is low to a light having a long wavelength, the transparent substrate being disposed on the light receiving surface.

14. The solid state imaging apparatus according to claim 13, wherein
the material having refractive index dispersion has an Abbe number of 40 or less.

15. The solid state imaging apparatus according to claim 14, wherein
the material having refractive index dispersion is polycarbonate resin (PC), polystyrene (PS), acrylonitrile styrene (AS resin), polymethacrylic styrene (MS resin), a glass-based material or TiO₂.

16. An electronic device, comprising a solid state imaging apparatus including a transparent substrate formed of a material having refractive index dispersion such that the refractive index is high to a light having a short wavelength and the refractive index is low to a light having a long wavelength, the transparent substrate being disposed on the light receiving surface.
